(19) United States
(12) Patent Application Publication
(10) Pub. No.: US 2002/0061639 A1
(43) Pub. Date: May 23, 2002

(54) Semiconductor device and method for manufacturing the same

(76) Inventor: Kazuichiroh Itonaga, Osaka (JP)

Correspondence Address: NIXON PEABODY, LLP, 8180 GREENSBORO DRIVE, SUITE 800, MCLEAN, VA, 22102, US

(21) Appl. No.: 09/966,741

(22) Filed: Oct. 1, 2001

(30) Foreign Application Priority Data
Oct. 2, 2000 (JP) 2000-302064

(51) Int. Cl. H01L 21/3205; H01L 21/4763

(52) U.S. Cl. 438/592; 438/683

(57) ABSTRACT

A cobalt film, which is a metal film, is deposited on a gate electrode, a heavily-doped source/drain region, etc., which is a semiconductor layer. Then, first thermal annealing is performed to cause a silicification reaction so as to form a polycrystalline cobalt silicide film. Then, ions such as arsenic ions or silicon ions are implanted into the cobalt silicide film so as to change the cobalt silicide film into an amorphous cobalt silicide film. Alternatively, nitrogen is introduced into the silicide film. After second thermal annealing, there is obtained a polycrystalline cobalt silicide film with substantially no agglomeration of crystal grains. Nitrogen may be introduced, before the formation of the cobalt silicide film, into a portion of the semiconductor layer that is to be silicified.

### BACKGROUND OF THE INVENTION

The present invention relates to a method for manufacturing a semiconductor device, and particularly to a method for forming a silicide layer by silicifying a metal.

In recent years, semiconductor devices have been made smaller and at a greater degree of integration. Along with the recent developments, a so-called “salicide process” is well known in the art as a method for reducing the resistance of a gate electrode or a diffusion layer of a MIS type semiconductor device. In a salicide process, a silicide film is formed in a gate electrode or a diffusion layer in a self-aligned manner by using a metal film of cobalt (Co), titanium (Ti), tungsten (W), etc. A method for manufacturing a semiconductor device using a conventional salicide process will now be described.

FIG. 10A to FIG. 10E are cross-sectional views illustrating steps in a method for manufacturing a semiconductor device using a conventional salicide process.

First, in the step of FIG. 10A, an insulative film 102 for trench device isolation is formed in a semiconductor substrate 101 so as to surround an active region, and a gate insulative film 103 made of a silicon oxide film is formed on the active region of the semiconductor substrate 101. Then, a polysilicon film is deposited on the substrate and patterned by lithography and dry etching so as to form a gate electrode 104 on the gate insulative film 103. Then, a low concentration of impurity ion is implanted into the active region using the gate electrode 104 and the device isolation insulative film 102 as masks so as to form an LDD region 105 in a self-aligned manner with respect to the gate electrode 104. Then, an oxide film is deposited on the substrate by using a CVD method, and the oxide film is etched back so as to form a side wall 106 made of an oxide film on the side surface of the gate electrode 104. Then, a high concentration of impurity ion is implanted into the active region using the gate electrode 104, the side wall 106 and the device isolation insulative film 102 as masks so as to form a heavily-doped source/drain region 107 in a self-aligned manner with respect to the gate electrode 104.

Then, in the step of FIG. 10B, a cobalt film 108 is deposited on the substrate by a sputtering method, and a titanium nitride film 109 is deposited on the cobalt film 108.

Then, in the step of FIG. 10c, the semiconductor substrate 101 is subjected to first rapid thermal annealing (RTA) at a temperature of about 400° C. to about 500° C. in a nitrogen gas atmosphere so as to allow silicon (Si) and cobalt (Co) to react with each other to form a cobalt-rich first cobalt silicide film 110a (a mixture of CoSi and Co₂Si) in exposed portions of the gate electrode 104 and the heavily-doped source/drain region 107. A portion of the cobalt film 108 that is on an insulative film such as the side wall 106 and the device isolation insulative film 102 is not silicified and remains to be an unreacted cobalt film 108a.

Then, in the step of FIG. 10D, the titanium nitride film 109 and the unreacted cobalt film 108a are selectively removed by using a solution such as a mixture of sulfuric acid and a hydrogen peroxide solution so as to selectively leave the polycrystalline first cobalt silicide film 110a on the gate electrode 104 and the heavily-doped source/drain region 107.

Then, in the step of FIG. 10E, the semiconductor substrate 101 is subjected to second rapid thermal annealing (RTA) at a temperature of about 800° C. to about 900° C. in a nitrogen gas atmosphere so as to convert the first cobalt silicide film 110a into a structurally-stable second cobalt silicide film 110b (CoSi₂ film). As a result, the sheet resistance of the second cobalt silicide film 110b is smaller than the sheet resistance of the first cobalt silicide film 110a. In this way, it is possible to reduce the resistance of the gate electrode 104 and the heavily-doped source/drain region 107.

However, a method for manufacturing a semiconductor device using the conventional salicide process as described above is likely to be influenced by agglomeration of the silicide film, whereby the resistance value of the silicide film increases. The crystal grains of a cobalt silicide formed on a gate electrode or a source/drain region through a silicification reaction agglomerate, by nature, when subjected to thermal annealing at a temperature of 650° or higher. Therefore, when the second rapid thermal annealing (800 to 900° C.) necessary to form a stable cobalt silicide film is performed, the cobalt silicide film may become partially disrupted or excessively thin due to agglomeration of the crystal grains.

FIG. 11A and FIG. 11B are enlarged cross-sectional views illustrating the structure of the semiconductor device in the steps of FIG. 10C and FIG. 10E, respectively. As illustrated in FIG. 11A, the first cobalt silicide film 110a, which has been formed by removing the unreacted cobalt film after the first rapid thermal annealing, is a single, continuous film of a generally uniform thickness including a large number of crystal grains of relatively small grain diameters. As illustrated in FIG. 11B, however, the cobalt crystal grains agglomerate together into larger crystal grains of greater grain diameters through the second rapid thermal annealing. Therefore, the second cobalt silicide film 110b may have portions that are excessively thin, thereby losing its uniformity in thickness, or may have disruptions 111 produced therein, thereby losing its continuity. As a result, the conductivity of the second cobalt silicide film 110b deteriorates and the resistance value increases substantially, whereby it is difficult to realize a reduced resistance in the gate electrode 104 and the heavily-doped source/drain region 107.

It is believed that the agglomeration of crystal grains in a silicide film occurs as follows. When the cobalt silicide film is heated to be 650° C. or higher, the cobalt atoms in each crystal grain start to move in surface diffusion. Then, the crystal grains are fluidized and move according to the movement of the cobalt atoms so that the interfacial energy is minimized, thereby changing the structure as a whole. Specifically, the crystal grains agglomerate by a plurality of crystal grains of close crystal orientations being united into a single crystal grain, or by a crystal grain growing into a larger crystal grain by incorporating grain boundary portions of other crystal grains.

Particularly with recent developments in the art reducing the dimensions of gate electrodes, interconnections, etc., (for example, the gate length has been reduced to about 0.1 μm), the agglomeration as described above may not only increase the resistance value but also cause silicide line disconnection (disruption). Moreover, since the depth of the source/drain region has also been reduced recently, a local increase in the size of crystal grains due to the agglomeration of crystal grains may cause a portion of the silicide film to come excessively close to the PN junction, thereby increasing the junction leak.

### SUMMARY OF THE INVENTION

An object of the present invention is to provide a semiconductor device, and a method for manufacturing the same, having a silicide film with a low resistance and a high reliability, by taking measures to suppress an increase in size, and a decrease in uniformity, of crystal grains due to agglomeration of crystal grains in a silicide film.

A first method of the present invention is a method for manufacturing a semiconductor device including a member which is partially silicified, including the steps of: (a) forming a metal film on a semiconductor layer of a substrate; (b) performing first thermal annealing to cause a silicification reaction between the metal film and the semiconductor layer so as to form a polycrystalline first silicide film on the semiconductor layer; (c) removing an unreacted portion of the metal film after the step (b); (d) implanting impurity ions into the first silicide film so as to change the first silicide film into an amorphous second silicide film; (e) performing second thermal annealing to change the amorphous second silicide film into a polycrystalline third silicide film, the third silicide film being at least a part of the member.

With this method, once the first silicide film is turned into the amorphous second silicide film, the polycrystalline structure is destroyed. Therefore, the crystal grains of the subsequently grown third silicide film are crystal grains that are grown newly and independently of the crystal grains of the first silicide film. Thus, it is possible to suppress an increase in size of the crystal grains in the third silicide film due to agglomeration, and to provide a semiconductor device having a silicide film with no disruptions and with a generally uniform thickness.

The semiconductor layer may be a part of a gate electrode of a MISFET, and the method may further include: a step of depositing a polysilicon film before the step (a); and a step of forming the gate electrode, to be the semiconductor layer, before or after the step (a). In this way, it is possible to provide a MISFET having a gate electrode with no disconnection and with a reduced resistance.

The semiconductor layer may be a part of a source/drain region of a MISFET, and the method may further include, before the step (a): a step of forming a gate insulative film and a gate electrode on an active region including the semiconductor layer; a step of forming an insulative side wall on a side surface of the gate electrode; and a step of forming a source/drain region, to be the semiconductor layer, in each of portions of the active region on both sides of the gate electrode. In this way, it is possible to provide a silicide layer in the source/drain region in a self-aligned manner with respect to the gate electrode.

The method may further include a step of forming a protection film on the substrate after the step (c) and before the step (d); and in the step (d), ions may be implanted into the silicide film via the protection film. In this way, there is provided an additional effect by the protection film of suppressing fluidization of the silicide crystal grains, whereby the effects described above can be more obtained reliably.

In such a case, it is preferred that the step of forming the protection film is performed at a temperature at which the silicide film does not agglomerate.

Moreover, it is preferred that the step of forming the protection film is performed at a temperature less than or equal to a temperature of the first thermal annealing.

In the step (d), the impurity ions may be implanted so as to reach into the semiconductor layer to change a surface portion of the semiconductor layer into an amorphous state. In this way, the crystal grains of the third silicide film grow more uniformly. Therefore, in a case where the semiconductor layer is a gate electrode, the gate resistance can be further reduced, and in a case where the semiconductor layer is a source/drain region, it is possible to obtain a semiconductor device in which spiking is suppressed and the junction leak is small.

It is preferred that, in the step (d), electrically neutral ions are used as the impurity ions.

In the step (d), silicon ions may be used as the electrically neutral ions. In this way, it is possible to compensate for the silicon consumption by the silicification reaction, whereby the effect of suppressing spiking is more pronounced.

A second method of the present invention is a method for manufacturing a semiconductor device including a member which is partially silicified, including the steps of: (a) forming a first metal film on a semiconductor layer of a substrate; (b) performing first thermal annealing to cause a silicification reaction between the first metal film and the semiconductor layer so as to form a metal-rich first silicide film on the semiconductor layer; (c) removing an unreacted portion of the first metal film after the step (b); (d) depositing a second metal film thinner than the first metal film on the substrate after the step (c); (e) performing second thermal annealing to form a second silicide film including a portion of the first silicide film that has been changed into a silicon-rich structure and a portion of the second metal film that has been silicified, the second silicide film being at least a part of the member; and (f) performing third thermal annealing to cause a silicification reaction between the second metal film and the semiconductor layer so as to form a third silicide film on the semiconductor layer.

With this method, even if the crystal grains agglomerate in the second silicide film during the second thermal annealing thereby resulting in thinned portions or disruptions, such thinned portions or disruptions are compensated for by portions of the second metal film that are silicified by the third thermal annealing. Therefore, it is possible to obtain a semiconductor device having a second silicide film with a relatively uniform thickness and with no disruptions. Moreover, since the second metal film is thinner than the first metal film, it is possible to avoid problems such as short-circuiting due to the silicide film intruding into a region of the second metal film that is not in contact with the semiconductor layer.

It is preferred that: the third silicide film is a metal-rich silicide film; and the method further includes a step of, after the step (f), performing fourth thermal annealing to change the third silicide film into a silicon-rich fourth silicide film, the second silicide film and the fourth silicide film being at least a part of the member.

A third method of the present invention is a method for manufacturing a semiconductor device including a member which is partially silicified, including the steps of: (a) forming a first metal film on a semiconductor layer of a substrate; (b) performing first thermal annealing to cause a silicification reaction between the first metal film and the semiconductor layer so as to form a metal-rich first silicide film on the semiconductor layer; (c) removing an unreacted portion of the first metal film after the step (b); (d) performing second thermal annealing to change the first silicide film into a silicon-rich second silicide film; (e) depositing a second metal film on the substrate after the step (d); (f) performing third thermal annealing to cause a silicification reaction between the second metal film and the semiconductor layer so as to form a metal-rich third silicide film on the semiconductor layer; and (g) performing fourth thermal annealing to change the third silicide film into a silicon-rich fourth silicide film, the second silicide film and the fourth silicide film being at least a part of the member.

With this method, even if the crystal grains agglomerate in the second silicide film during the second thermal annealing thereby resulting in disruptions, such disruptions are compensated for by the fourth silicide film, which is produced through silicification of the second metal film. Therefore, it is possible to obtain a semiconductor device having a continuous silicide film with no disruptions. Moreover, since the second metal film is thinner than the first metal film, it is possible to avoid problems such as short-circuiting due to the silicide film introducing into a region of the second metal film that is not in contact with the semiconductor layer.

In the step (a), a titanium film may be formed as the first metal film; and in the step (g), a cobalt film may be formed as the second silicide film. In this way, the third and fourth thermal annealing can be performed without influencing the crystal grains in the second silicide film, which is made of a titanium silicide whose reaction temperature is high.

A fourth method of the present invention is a method for manufacturing a semiconductor device including a member which is partially silicified, including the steps of: (a) forming a metal film whose main component is cobalt on a semiconductor layer of a substrate; (b) performing first thermal annealing to cause a silicification reaction between the metal film and the semiconductor layer so as to form a polycrystalline first cobalt silicide film on the semiconductor layer; (c) removing an unreacted portion of the metal film after the step (b); and (d) after the step (c), performing second thermal annealing at a temperature of 725° C. or less to change the first cobalt silicide film into a second cobalt silicide film, the second cobalt silicide film being at least a part of the member.

With this method, CoSi₂ crystal grains are less likely to occur in the cobalt silicide film, which is produced through the second thermal annealing, whereby it is possible to provide a semiconductor device having a continuous silicide film with no disruptions and with a generally uniform thickness.

The method may further include: a step of forming a protection film on the substrate so as to cover the second cobalt silicide film after the step (d); and a step of performing third thermal annealing at a temperature higher than that of the second thermal annealing, with the second cobalt silicide film being covered by the protection film. In this way, it is possible to suppress the junction leak in the diffusion layer of the semiconductor substrate while suppressing disconnection of a gate electrode, a gate line, etc., due to a reduction in the width thereof.

A fifth method of the present invention is a method for manufacturing a semiconductor device including a member which is partially silicified, including the steps of: (a) forming a metal film on a semiconductor layer of a substrate; (b) performing first thermal annealing to cause a silicification reaction between the metal film and the semiconductor layer so as to form a polycrystalline first silicide film on the semiconductor layer; (c) removing an unreacted portion of the metal film after the step (b); (d) introducing nitrogen into the first silicide film before, in, or after, any of the steps (a) to (c); and (e) after the step (d), performing second thermal annealing to change the first silicide film into a second silicide film, the second silicide film being at least a part of the member.

With this method, agglomeration of crystal grains in a silicide film after the second thermal annealing is less likely to occur, whereby it is possible to provide a semiconductor device having a continuous silicide film with no disruptions and with a generally uniform thickness.

In the step (d), the nitrogen may be introduced so that a nitrogen concentration in the semiconductor layer is 10¹⁷·cm³ or less after the step (e). In this way, it is possible to avoid an adverse influence on the activation of the impurity in the semiconductor layer.

The semiconductor layer may be a part of a source/drain region of a MISFET, and the method may further include, before the step (a): a step of forming a gate insulative film and a gate electrode on an active region including the semiconductor layer; a step of forming an insulative side wall on a side surface of the gate electrode; and a step of forming a source/drain region by implanting impurity ions into each of portions of the active region on both sides of the gate electrode and then activating the impurity, wherein the step (d) may be performed after the step of forming a source/drain region and before the step (a).

The method may further include a pre-cleaning step of irradiating a surface of the semiconductor layer with plasma before the step (a), wherein the step (d) may be performed by introducing nitrogen into the semiconductor layer, in advance, by using nitrogen-containing plasma in the pre-cleaning step.

A first semiconductor device of the present invention includes: a substrate including a semiconductor layer; and a silicide layer formed on the semiconductor layer, the silicide layer being obtained by combining together a first metal silicide film and a second metal silicide film.

In such a semiconductor device, even if the crystal grains in the second silicide film agglomerate, uneven distributions of the crystal grains due to agglomeration, e.g., disruptions or thinned portions, are compensated for by the fourth silicide film. Therefore, it is possible to obtain a continuous silicide film with a relatively uniform thickness.

The semiconductor layer and the silicide layer may together form a gate electrode or a source/drain region of a MISFET.

The first metal silicide film may be a titanium silicide film; and the second metal silicide film may be a cobalt silicide film. In this way, the manufacturing process can be simplified by utilizing a difference in the silicification reaction temperature.

A second semiconductor device of the present invention includes: a substrate including a semiconductor layer; and a silicide layer formed on the semiconductor layer and containing nitrogen.

In such a semiconductor device, thickness variations or disruptions in the silicide film due to agglomeration can be suppressed, whereby it is possible to obtain a semiconductor device having a silicide film with a good thickness uniformity.

It is preferred that the silicide film is a cobalt silicide film.

It is preferred that the silicide film has a polycrystalline layered structure.

A third semiconductor device of the present invention includes: a substrate including a semiconductor layer; and a silicide film formed on the semiconductor layer and having a polycrystalline layered structure.

It is acknowledged that agglomeration of crystal grains of cobalt silicide hardly occurs in the silicide film having the polycrystalline layered structure.

### BRIEF DESCRIPTION OF THE DRAWINGS

FIG. 1A to FIG. 1C are cross-sectional views illustrating some steps in a method for manufacturing a semiconductor device according to a first embodiment, up to the formation of a first silicide film.

FIG. 2A to FIG. 2C are cross-sectional views illustrating some steps in the method for manufacturing a semiconductor device according to the first embodiment, from the removal of an unreacted cobalt film up to the formation of a third silicide film.

FIG. 3A to FIG. 3C are cross-sectional views illustrating some steps in a method for manufacturing a semiconductor device according to a second embodiment, up to the formation of a first silicide film.

FIG. 4A to FIG. 4C are cross-sectional views illustrating some steps in the method for manufacturing a semiconductor device according to the second embodiment, from the removal of an unreacted cobalt film up to the formation of a third silicide film.

FIG. 5A to FIG. 5C are cross-sectional views illustrating some steps in a method for manufacturing a semiconductor device according to a third embodiment, up to the formation of a first silicide film.

FIG. 6A to FIG. 6C are cross-sectional views illustrating some steps in the method for manufacturing a semiconductor device according to the third embodiment, from the formation of a second metal film and a protection film up to the formation of a second silicide film.

FIG. 7A to FIG. 7C are cross-sectional views illustrating some steps in a method for manufacturing a semiconductor device according to a fourth embodiment, up to the formation of a first silicide film.

FIG. 8A to FIG. 8C are cross-sectional views illustrating some steps in the method for manufacturing a semiconductor device according to the fourth embodiment, from the formation of a second silicide film up to the formation of a third silicide film.

FIG. 9A to FIG. 9C are cross-sectional views illustrating some steps in the method for manufacturing a semiconductor device according to the fourth embodiment, from the removal of an unreacted second cobalt film up to the formation of a fourth silicide film.

FIG. 10A to FIG. 10E are cross-sectional views illustrating steps in a method for manufacturing a semiconductor device having a conventional salicide structure.

FIG. 11A and FIG. 11B are enlarged views of FIG. 10D and FIG. 10E, respectively.

FIG. 12 shows measurement results of a junction leak of a MISFET having a silicide film made by a conventional method and that of a MISFET having a silicide film into which nitrogen ions are introduced.

FIG. 13 is data showing the resistance of a gate electrode, a gate line, etc., in the presence of nitrogen and that in the absence of nitrogen.

FIG. 14A and FIG. 14B are bright-field and dark-field TEM photographs showing a silicide layer formed by nitrogen ion implantation, respectively.

FIG. 14C and FIG. 14D are bright-field and dark-field TEM photographs showing a silicide layer formed without nitrogen ion implantation, respectively.

### DESCRIPTION OF PREFERRED EMBODIMENTS

Preferred embodiments of the present invention will now be described with reference to the drawings.

(First Embodiment)

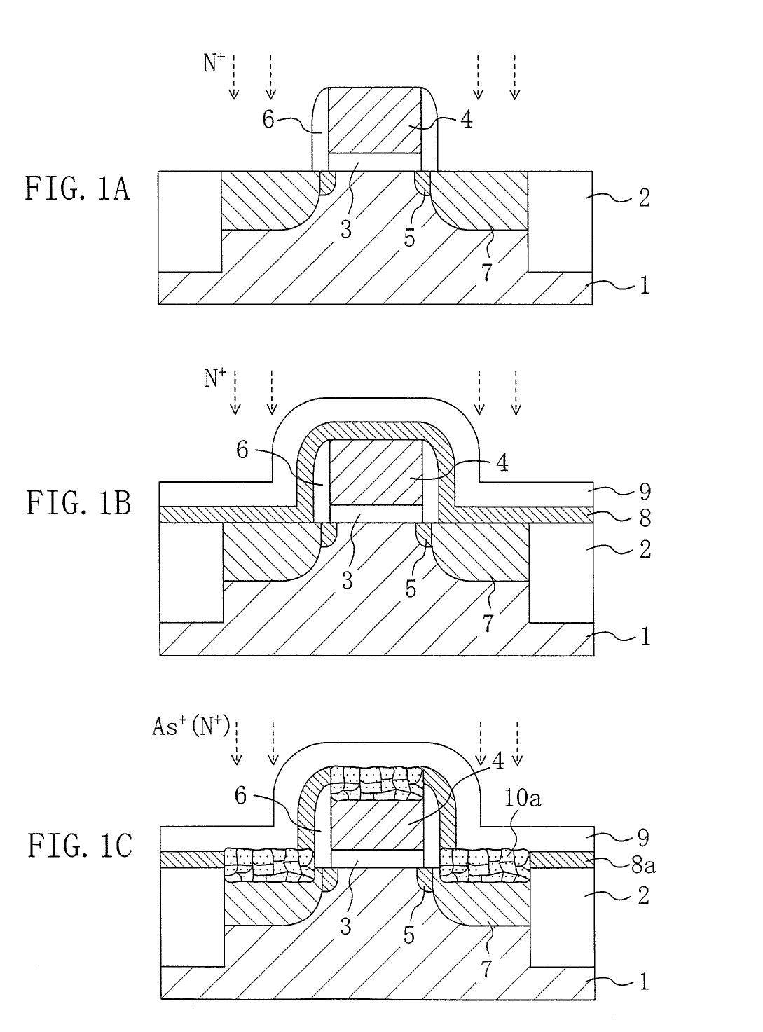

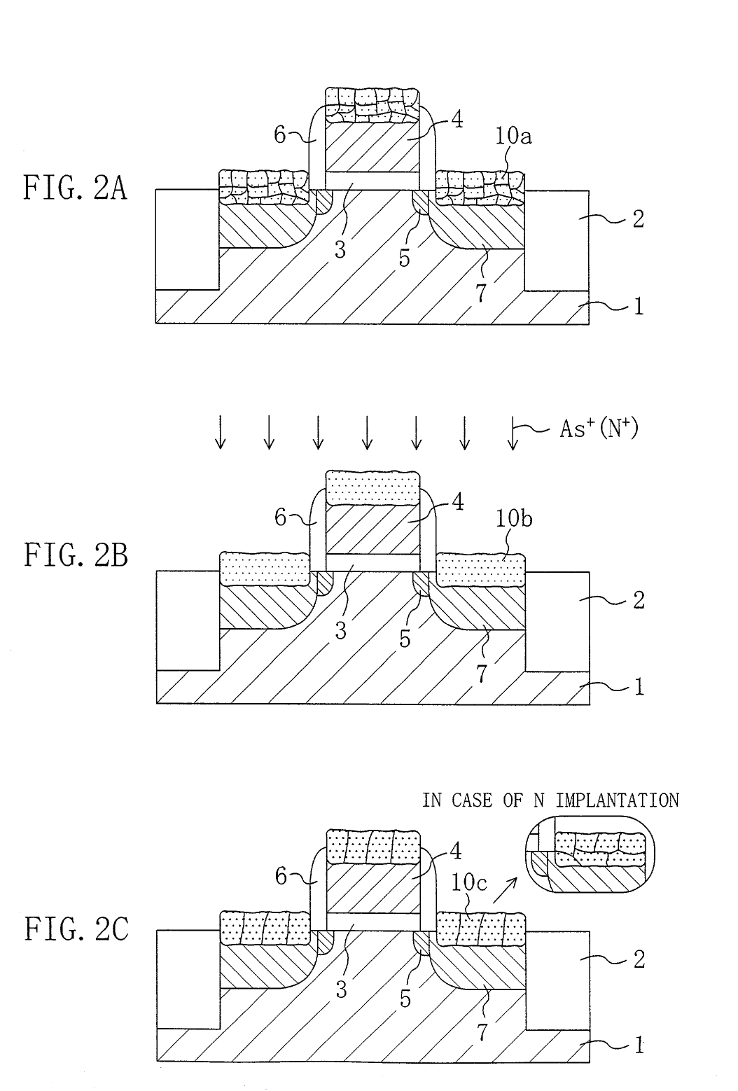

FIG. 1A to FIG. 1C and FIG. 2A to FIG. 2C are cross-sectional views illustrating a method for manufacturing a semiconductor device according to the first embodiment of the present invention.

First, in the step of FIG. 1A, an insulative film 2 for trench device isolation is formed in a p-type semiconductor substrate 1 so as to surround an active region, and a gate insulative film 3 made of a silicon oxide film is formed on the active region of the semiconductor substrate 1. Then, a polysilicon film is deposited on the substrate and patterned by lithography and dry etching so as to form a gate electrode 4 on the gate insulative film 3. Then, a low concentration of n-type impurity ion is implanted into the active region using the gate electrode 4 and the device isolation insulative film 2 as masks so as to form an LDD region 5 in a self-aligned manner with respect to the gate electrode 4. Then, an oxide film is deposited on the substrate by using a CVD method, and the oxide film is etched back so as to form a side wall 6 made of an oxide film on the side surface of the gate electrode 4. Then, a high concentration of n-type impurity ion is implanted into the active region using the gate electrode 4, the side wall 6 and the device isolation insulative film 2 as masks so as to form a heavily-doped source/drain region 7 in a self-aligned manner with respect to the gate electrode 4.

In this step, nitrogen ions (N⁺ or N₂⁺) may be implanted, instead of the implantation of arsenic ions illustrated in FIG. 2B, after activating the impurity implanted into the heavily-doped source/drain region 7. Also in this way, disruptions or substantial surface irregularities in the silicide film due to silicide film agglomeration can be suppressed.

Moreover, instead of implanting nitrogen ions, plasma may be generated in a nitrogen-containing atmosphere to introduce nitrogen plasma into the gate electrode 4 and the heavily-doped source/drain region 7 when performing pre-cleaning, which is a pre-treatment before sputtering the cobalt film. Typically, pre-cleaning is a process of reverse-sputtering a substance in a base layer by irradiating the base layer with Ar ions. Prior to a silicide process, the pre-cleaning is performed for the purpose of removing an oxide film from the surface of a semiconductor layer (the gate electrode 4 or the heavily-doped source/drain region 7) on which a silicide layer is to be formed.

Then, in the step of FIG. 1B, a cobalt film 8 having a thickness of about 8 nm is deposited on the substrate by using a sputtering method, and a titanium nitride film 9 having a thickness of about 20 nm is deposited as a protection film on the cobalt film 8.

In this step, nitrogen ions (N⁺ or N₂⁺) may be implanted, instead of the implantation of arsenic ions illustrated in FIG. 2B, before or after the deposition of the titanium nitride film 9. Also in this way, disruptions or substantial surface irregularities in the silicide film due to silicide film agglomeration can be suppressed.

Then, in the step of FIG. C, the semiconductor substrate 1 is subjected to first rapid thermal annealing (RTA) for about 60 seconds at a temperature of about 400° C. to about 500° C. in a nitrogen gas atmosphere so as to allow silicon (Si) and cobalt (Co) to react with each other to form a cobalt-rich first cobalt silicide film 10a (a mixture of Co₂Si and CoSi) in exposed portions of the gate electrode 4 and the heavily-doped source/drain region 7. It is believed that the first silicide film 10a is an aggregate of minute crystals, and clear crystal grain boundaries as illustrated in FIG. 1C do not always appear. In this process, a portion of the cobalt film 8 that is on an insulative film such as the side wall 6 and the device isolation insulative film 2 is not silicified and remains to be an unreacted cobalt film 8a. Note that the first rapid thermal annealing may be performed in a vacuum or an argon atmosphere instead of a nitrogen gas atmosphere.

In this step, arsenic ions (As⁺) or nitrogen ions (N⁺ or N₂⁺) may be implanted, instead of the implantation of arsenic ions illustrated in FIG. 2B. Also in this way, disruptions or substantial surface irregularities in the silicide film due to silicide film agglomeration can be suppressed.

Then, in the step of FIG. 2A, the titanium nitride film 9 and the unreacted cobalt film 8a are selectively removed by using a solution such as a mixture of sulfuric acid and a hydrogen peroxide solution so as to selectively leave the polycrystalline first cobalt silicide film 10a on the gate electrode 4 and the heavily-doped source/drain region 7.

Then, in the step of FIG. 2B, n-type impurity ions, e.g., arsenic ions (As⁺), are implanted into the first cobalt silicide film 10a at a dose of about 1×10¹⁴ atoms/cm² so as to turn at least the first cobalt silicide film 10a into an amorphous state to obtain an amorphous second cobalt silicide film 10b. In this process, it is preferred to implant ions so that the ions reach into the surface portions of the gate electrode 4 and the heavily-doped source/drain region 7 under the first cobalt silicide film 10a to a depth to which they will be converted into cobalt silicide films through subsequent second rapid thermal annealing, so as to turn the polysilicon or silicon into an amorphous state.

In this step, nitrogen ions (N⁺ or N₂⁺) may be implanted, instead of arsenic ions. Also in this way, disruptions or substantial surface irregularities in the silicide film due to silicide film agglomeration can be suppressed. The nitrogen ion is preferably N₂⁺ rather than N⁺, in which case the silicide film and the underlying polysilicon or silicon are more easily turned into an amorphous state.

Then, in the step of FIG. 2C, the semiconductor substrate 1 is subjected to second rapid thermal annealing (RTA) for about 10 seconds at a temperature of about 800° C. to about 900° C. in a nitrogen gas atmosphere so as to convert the amorphous second cobalt silicide film 10b into a structurally-stable, polycrystalline third cobalt silicide film 10c (CoSi₂). Note that the second rapid thermal annealing may be performed in a vacuum or an argon atmosphere instead of a nitrogen gas atmosphere.

Note that if arsenic ions are implanted in the step of FIG. 1C or FIG. 2B, the third cobalt silicide film 10c has a so-called “bamboo structure” where there is substantially no laterally-extending grain boundaries, as illustrated in FIG. 2C, whereas if nitrogen ions are implanted in any of the steps of FIG. 1A, FIG. 1B, FIG. 1C and FIG. 2B, there will be a polycrystalline structure having therein laterally-extending grain boundaries, resulting in a generally layered structure where crystal grains are layered on one another, as illustrated in the upper right corner of FIG. 2C.

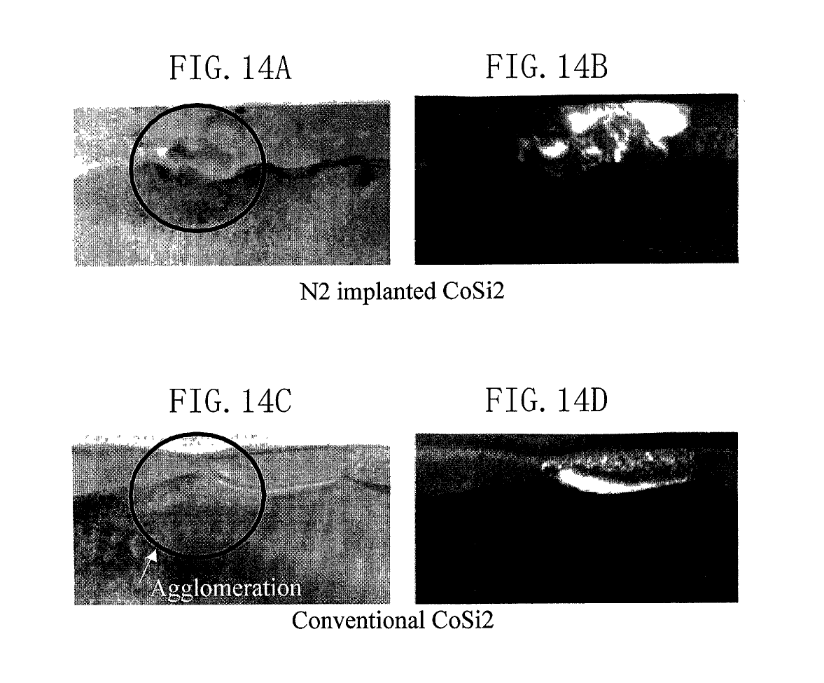

FIG. 14A and FIG. 14B are bright-field and dark-field TEM photographs showing the silicide layer formed by nitrogen ion implantation, respectively. FIG. 14C and FIG. 14D are bright-field and dark-field TEM photographs showing a conventional silicide layer formed without nitrogen ion implantation. FIG. 14A to FIG. 14D shows the third cobalt silicide film obtained by implanting N₂ ions into the first cobalt silicide film with an acceleration energy of 20 KeV at a dose of 1×10¹⁵·cm⁻² after annealing for activating the impurities in the source/drain region.

As shown in FIG. 14A and FIB. 14B, nitrogen ion implantation forms a silicide film having a grain boundary in a transverse direction, instead of so-called bamboo structure, i.e., having a polycrystalline layered structure. Wherein, the size of the grains is small and CoSi₂ grains are laminated up and down. In addition, the upper surface of the cobalt silicide film is smooth. In other words, due to the thermal treatment, CoSi₂ grains of the lower layer enter into the upper CoSi₂ grain boundary and no agglomeration occurs in the lower CoSi₂ film.

Contrarily, as shown in FIG. 14C and FIG. 14D, the cobalt silicide film formed without nitrogen ion implantation has the so-called bamboo structure and has no grain boundary in the transverse direction. Further, the size of the grains is large and agglomeration occurs. The upper surface of the cobalt silicide film and the interface between the cobalt silicide film and the underlayer is rough.

With the manufacturing method of the present embodiment, arsenic ions are implanted into the polycrystalline first cobalt silicide film 10a, and the first cobalt silicide film 10a is turned into the amorphous second cobalt silicide film 10b, in the step of FIG. 2B, after which the polycrystalline third cobalt silicide film 10c is formed through the second rapid thermal annealing in the step of FIG. 2C. Therefore, agglomeration of crystal grains does not occur through the second rapid thermal annealing, as in the conventional manufacturing method, and the entirety of the amorphous second cobalt silicide film 10b is converted into the stable third cobalt silicide film 10c made of generally uniform polycrystals. Therefore, partial disruptions are unlikely to occur in the final cobalt silicide film 10c, and it is possible to form the third cobalt silicide film 10c as a single, continuous film having a uniform thickness. Thus, it is possible to reliably realize a reduced resistance in the gate electrode 4 and the heavily-doped source/drain region 7. Moreover, even when the width of the gate electrode or the gate line is reduced, it is possible to avoid partial disruptions from occurring therein, and even when the depth of the heavily-doped source/drain region 7 is reduced, the junction leak can be suppressed because it is possible to obtain a silicide film having a uniform thickness that is made of crystal grains of relatively uniform grain diameters.

Moreover, crystal grains of the third cobalt silicide film 10c grow uniformly during the second rapid thermal annealing by turning the surface portions of the gate electrode 4 and the heavily-doped source/drain region 7 under the first cobalt silicide film 10a into an amorphous state in the process of implanting ions into the first cobalt silicide film 10a. Therefore, it is possible to more effectively realize a reduced resistance in the gate electrode 4, and it is possible to suppress an abnormal junction leak since spiking is less likely to occur under the heavily-doped source/drain region 7.

Note that while the first cobalt silicide film 10a is turned into an amorphous state by implanting arsenic ions in the step of FIG. 2B in the embodiment described above, the first cobalt silicide film 10a may be turned into an amorphous state alternatively by implanting silicon (Si) ions instead of arsenic ions. In the case where silicon ions are implanted, it is possible to compensate for the silicon consumption in the gate electrode 4 and the heavily-doped source/drain region 7 by the reaction of the second rapid thermal annealing, whereby it is possible to suppress the junction leak due to spiking. As a result, the sheet resistance of the third cobalt silicide film 10c is reduced, and it is possible to realize a reduced resistance in the gate electrode 4 and the heavily-doped source/drain region 7. Alternatively, an element that is electrically neutral and capable of turning the first cobalt silicide film b1a into an amorphous state, such as argon (Ar), germanium (Ge) or tin (Sn), may be implanted instead of arsenic. Also in this way, disruptions or substantial surface irregularities in the silicide film due to silicide film agglomeration can be suppressed, as in the case where arsenic ions are implanted.

When ions of an impurity to be a dopant for carrier generation are implanted into a silicide film on a source/drain region, it is preferred that an impurity of the same conductivity type as that of the source/drain region is implanted. For example, in a case where the source/drain region is of p type, gallium (Ga) or indium (In) may be implanted, whereas in a case where the source/drain region is of n type, arsenic (As) or antimony (Sb) may be implanted. This similarly applies to a case where ions are implanted into a silicide film on a gate electrode having a dual gate structure.

The timing at which to implant arsenic ions is not limited to the step of FIG. 2C, but may alternatively be the step of FIG. 1C.

Instead of arsenic ions, nitrogen may be introduced into a portion of a semiconductor layer (the gate electrode 4 or the heavily-doped source/drain region 7) where a silicide film is to be formed, in the step of FIG. 1A or FIG. 1B (i.e., before forming the first cobalt silicide film 10a). Nitrogen may be introduced into a semiconductor layer (the gate electrode 4 or the heavily-doped source/drain region 7) in the step of FIG. 1B or FIG. 2B. However, it is believed that in a case where nitrogen ions are implanted, the film is not turned into an amorphous state as illustrated in FIG. 2B.

When nitrogen ions are implanted, a polycrystalline layered structure will result, as illustrated in the upper right corner of FIG. 2C, FIG. 14A and FIG. 14B, through the second rapid thermal annealing. It has been confirmed that, in such a case, agglomeration of the cobalt silicide crystal grains is not likely to occur, unlike in the prior art, even if the second rapid thermal annealing is performed. Therefore, it is possible to provide a MIS transistor having a continuous silicide film with no disruptions and with a generally uniform thickness. Thus, it is possible to realize a reduced resistance in the gate electrode 4 and the heavily-doped source/drain region 7.

Although the mechanism of this has not been elucidated completely, one assumption is as follows. One can assume that, in the case of a polycrystalline layered structure as illustrated in the upper right corner of FIG. 2C, atoms in a crystal on one side of a laterally-extending grain boundary and atoms in an adjacent crystal on the other side of the laterally-extending grain boundary diffuse in opposite directions, thereby inhibiting diffusion, and the presence of nitrogen suppresses the atomic diffusion itself, thereby inhibiting the agglomeration. This is because one can assume that the crystal agglomeration occurs when atoms such as metal atoms or silicon atoms in crystal grains diffuse in a certain direction (e.g., clockwise), thereby producing a driving force that reduces the surface area of the crystal grains.

The introduction of nitrogen into a silicide film, as the introduction of arsenic, has an advantage that it has little influence on the carrier concentration of a semiconductor layer.

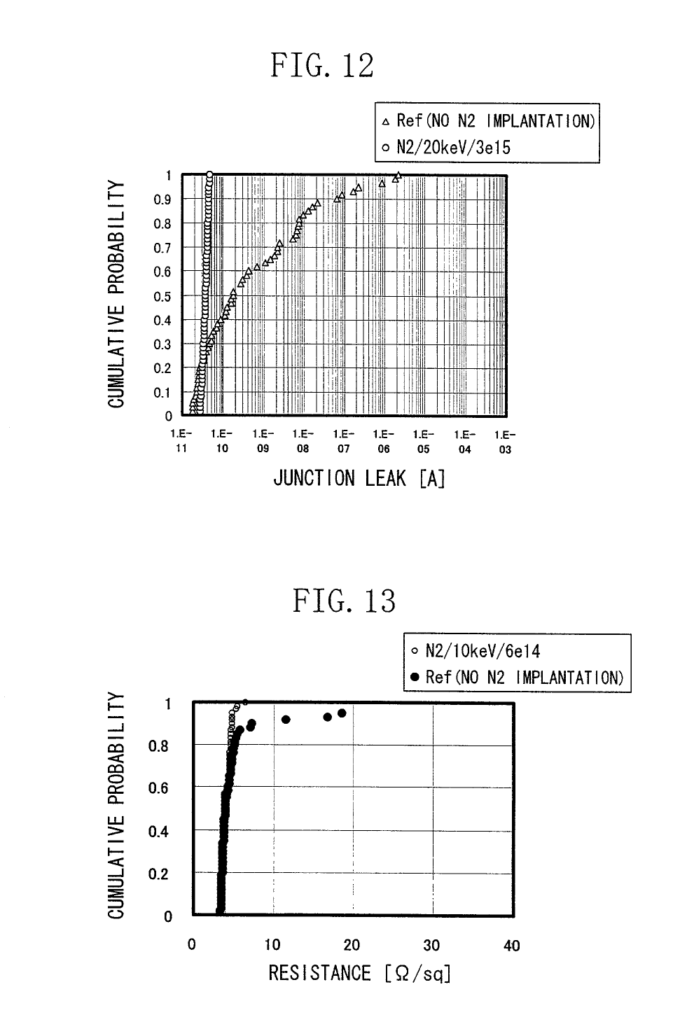

FIG. 12 shows measurement results of a junction leak of a MISFET having a silicide film made by a conventional method (without N₂ implantation) and that of a MISFET having a silicide film into which nitrogen ions are introduced. The nitrogen ions are implanted with an acceleration energy of 20 keV and a dose of 1×10¹⁵·cm⁻². As illustrated in FIG. 12, MIS transistors formed by a conventional method without introduction of nitrogen into the silicide film have substantial junction leak variations, whereas there is little variations among the junction leak values in MIS transistors having a silicide film into which nitrogen is introduced. As a result, there will be no increase in the junction leak even when the CoSi₂ film formation temperature or the thermal annealing temperature in subsequent steps is set to about 650° C. to about 700° C. Therefore, it is possible to perform thermal annealing at about 700° C. without deteriorating the short-channel characteristics of the transistor.

In the case where nitrogen is introduced, it is preferred that nitrogen ions are implanted with an N₂ dose of 2×10¹⁴ to 2×10¹⁵·cm⁻². When the dose is less than 2×10¹⁴·cm⁻², the effect of suppressing the silicide crystal agglomeration cannot be obtained sufficiently. When the dose is greater than 2×10¹⁵·cm⁻², the interface resistance at the CoSi₂/Si interface increases.

The implanted nitrogen will be introduced not only into the silicide film but also into semiconductor layers (in the present embodiment, the gate electrode 4, the heavily-doped source/drain region 7, the LDD region 5, etc.). It is preferred that the nitrogen concentration in the semiconductor layers (the gate electrode 4, the heavily-doped source/drain region 7 and the LDD region 5) other than the silicide film is 1×10¹⁷·cm⁻³ or less after the formation of the third cobalt silicide film 10c. In other words, it is preferred that a region containing nitrogen at a concentration greater than 1×10¹⁷ ·cm⁻³ is limited to the silicide film. When the nitrogen concentration is high, the impurities (arsenic, phosphorus, boron, etc.) in the semiconductor layers may not be activated sufficiently, thereby reducing the drain current of the MIS transistor and excessively increasing the resistance of the gate electrode and the gate line.

FIG. 13 is data showing the sheet resistance of a gate electrode, a gate line, etc., in the presence of nitrogen and that in the absence of nitrogen. As illustrated in FIG. 13, if nitrogen is not introduced, samples having large sheet resistance values occur at a considerably high probability. In contrast, if nitrogen ions (N₂⁺) are implanted with an acceleration energy of 10 kev and a dose of 6×10¹⁴·cm⁻², no samples having large sheet resistance values occur and stable sheet resistance values are obtained. Thus, an advantageous effect of the present invention is demonstrated.

In the present embodiment and in other subsequent embodiments, the silicide film to be formed is not limited to a cobalt silicide film. Alternatively, the present invention may be used with any of various other metal silicide films, including a titanium silicide film, a tungsten silicide film, a nickel silicide film, a molybdenum silicide film, and tantalum silicide film. It should be noted that a cobalt silicide film has an advantage that it has little influence on the impurity profile in the semiconductor substrate because it can be subjected to a silicification reaction at a lower temperature than a titanium silicide film.

(Second Embodiment)

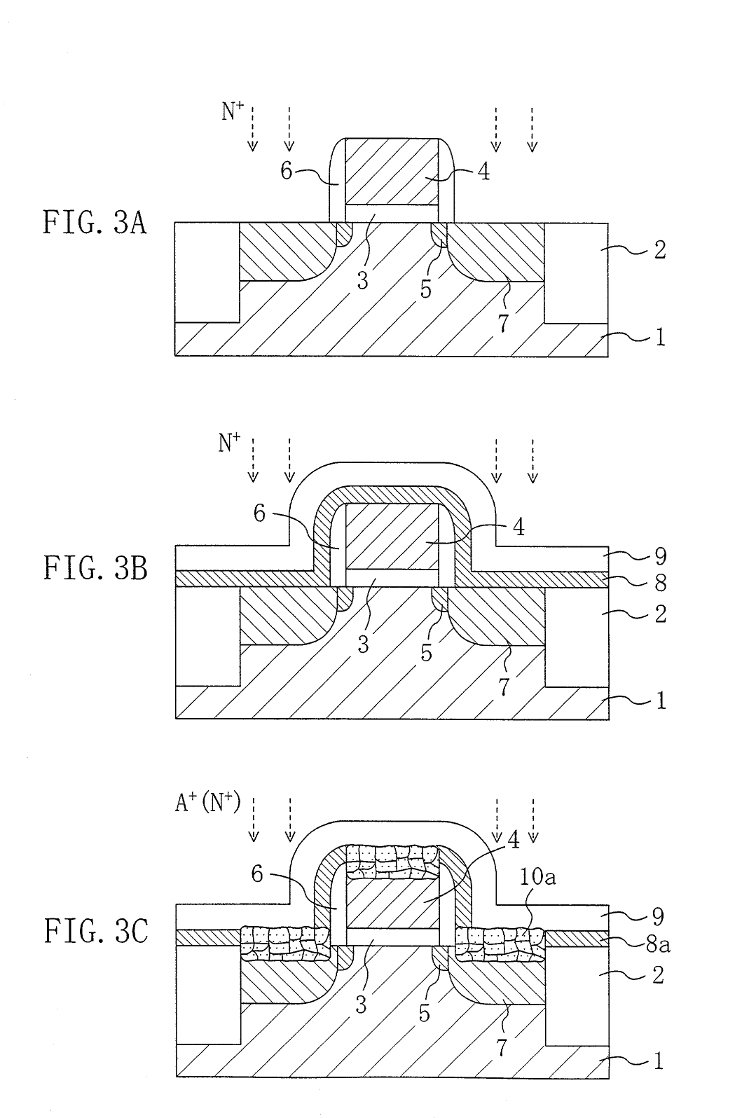

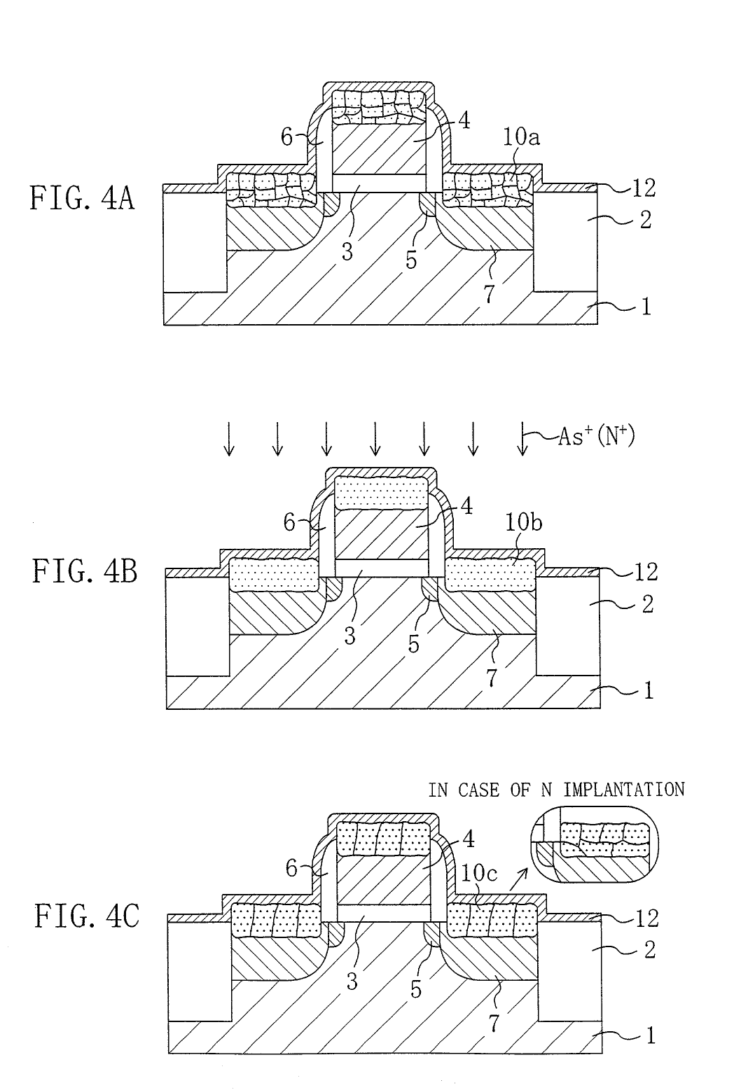

FIG. 3A to FIG. 3C and FIG. 4A to FIG. 4C are cross-sectional views illustrating a method for manufacturing a semiconductor device according to the second embodiment of the present invention.

First, in the step of FIG. 3A, an insulative film 2 for trench device isolation is formed in a p-type semiconductor substrate 1 so as to surround an active region, and a gate insulative film 3 made of a silicon oxide film is formed on the active region of the semiconductor substrate 1. Then, a polysilicon film is deposited on the substrate and patterned by lithography and dry etching so as to form a gate electrode 4 on the gate insulative film 3. Then, a low concentration of n-type impurity ion is implanted into the active region using the gate electrode 4 and the device isolation insulative film 2 as masks so as to form an LDD region 5 in a self-aligned manner with respect to the gate electrode 4. Then, an oxide film is deposited on the substrate by using a CVD method, and the oxide film is etched back so as to form a side wall 6 made of an oxide film on the side surface of the gate electrode 4. Then, a high concentration of n-type impurity ion is implanted into the active region using the gate electrode 4, the side wall 6 and the device isolation insulative film 2 as masks so as to form a heavily-doped source/drain region 7 in a self-aligned manner with respect to the gate electrode 4.

In this step, nitrogen ions (N⁺ or N₂⁺) may be implanted, instead of the implantation of arsenic ions illustrated in FIG. 4B, after activating the impurity implanted into the heavily-doped source/drain region 7. Also in this way, disruptions or substantial surface irregularities in the silicide film due to silicide film agglomeration can be suppressed.

Moreover, instead of implanting nitrogen ions, plasma may be generated in a nitrogen-containing atmosphere to introduce nitrogen plasma into the gate electrode 4 and the heavily-doped source/drain region 7 when performing pre-cleaning, which is a pre-treatment before sputtering the cobalt film.

Then, in the step of FIG. 3B, a cobalt film 8 having a thickness of about 8 nm is deposited on the substrate by using a sputtering method, and a titanium nitride film 9 having a thickness of about 20 nm is deposited as a protection film on the cobalt film 8.

In this step, nitrogen ions (N⁺ or N₂⁺) may be implanted, instead of the implantation of arsenic ions illustrated in FIG. 4B, before or after the deposition of the titanium nitride film 9. Also in this way, disruptions or substantial surface irregularities in the silicide film due to silicide film agglomeration can be suppressed.

Then, in the step of FIG. 3C, the semiconductor substrate 1 is subjected to first rapid thermal annealing (RTA) for about 60 seconds at a temperature of about 400° C. to about 500° C. in a nitrogen gas atmosphere so as to allow silicon (Si) and cobalt (Co) to react with each other to form a cobalt-rich first cobalt silicide film 10a (a mixture of Co₂Si and CoSi) in exposed portions of the gate electrode 4 and the heavily-doped source/drain region 7. It is believed that the first silicide film 10a is an aggregate of minute crystals, and clear crystal grain boundaries as illustrated in FIG. 3C do not always appear. In this process, a portion of the cobalt film 8 that is on an insulative film such as the side wall 6 and the device isolation insulative film 2 is not silicified and remains to be an unreacted cobalt film 8a. Note that the first rapid thermal annealing may be performed in a vacuum or an argon atmosphere instead of a nitrogen gas atmosphere.

In this step, arsenic ions (As⁺) or nitrogen ions (N⁺ or N₂⁺) may be implanted, instead of the implantation of arsenic ions illustrated in FIG. 4B. Also in this way, disruptions or substantial surface irregularities in the silicide film due to silicide film agglomeration can be suppressed.

Then, in the step of FIG. 4A, the titanium nitride film 9 and the unreacted cobalt film 8a are selectively removed by using a solution such as a mixture of sulfuric acid and a hydrogen peroxide solution so as to selectively leave the polycrystalline first cobalt silicide film 10a on the gate electrode 4 and the heavily-doped source/drain region 7. Then, a protection film 12 made of a CVD oxide film having a thickness of about 20 nm is deposited on the substrate. In this process, it is preferred that the temperature at which the protection film 12 is deposited is lower than the temperature at which agglomeration of the first silicide film occurs, e.g., 650° C. or less in a case where a cobalt silicide film is used as in the present embodiment. Moreover, it is more preferred that the temperature at which the protection film 12 is deposited is about the same or lower than the temperature of the first rapid thermal annealing. Note that the protection film 12 is not limited to a CVD oxide film, but may alternatively be an insulative film such as a plasma oxide film or a plasma nitride film, or a conductive film such as a titanium nitride film.

Then, in the step of FIG. 4B, n-type impurity ions, e.g., arsenic ions (As⁺), are implanted into the first cobalt silicide film b1a through the protection film 12 at a dose of about 1×10¹⁴ atoms/cm² so as to turn at least the first cobalt silicide film 10a into an amorphous state to obtain an amorphous second cobalt silicide film 10b. In this process, it is preferred to implant ions so that the ions reach into the surface portions of the gate electrode 4 and the heavily-doped source/drain region 7 under the first cobalt silicide film 10a to a depth to which they will be converted into cobalt silicide films through subsequent second rapid thermal annealing, so as to turn the polysilicon or silicon into an amorphous state.

In this step, nitrogen ions (N⁺ or N₂⁺) may be implanted, instead of arsenic ions. Also in this way, disruptions or substantial surface irregularities in the silicide film due to silicide film agglomeration can be suppressed. The nitrogen ion is preferably N₂⁺ rather than N⁺, in which case the silicide film and the underlying polysilicon or silicon are more easily turned into an amorphous state.

Then, in the step of FIG. 4C, the semiconductor substrate 1 is subjected to second rapid thermal annealing (RTA) for about 10 seconds at a temperature of about 800° C. to about 900° C. in a nitrogen gas atmosphere so as to convert the amorphous second cobalt silicide film 10b into a structurally-stable, polycrystalline third cobalt silicide film 10c (CoSi₂). Note that the second rapid thermal annealing may be performed in a vacuum or an argon atmosphere instead of a nitrogen gas atmosphere.

Note that if arsenic ions are implanted in the steps of FIG. 3C or FIG. 4B, the third cobalt silicide film 10c has a so-called “bamboo structure” where there is substantially no laterally-extending grain boundaries, as illustrated in FIG. 4C, whereas if nitrogen ions are implanted in any of the steps of FIG. 3A, FIG. 3B, FIG. 3C and FIG. 4B, there will be a polycrystalline structure having therein laterally-extending grain boundaries, resulting in a generally layered structure where crystal grains are layered on one another, as illustrated in the upper right corner of FIG. 4C.

Then, if the protection film 12 is an insulative film, the protection film 12 may be left as it is, and an interlayer insulative film may be formed on the protection film 12. If the protection film 12 is a conductive film such as a titanium nitride film, an interlayer insulative film may be formed after selectively removing the protection film 12.

With the manufacturing method of the present embodiment, the protection film 12 is deposited on the first cobalt silicide film b1a in the step of FIG. 4A, and ions are implanted into the first cobalt silicide film 10a via the protection film 12 to turn the first cobalt silicide film 10a into the amorphous second cobalt silicide film 10b, in the step of FIG. 4B, after which the third cobalt silicide film 10c is formed through the second rapid thermal annealing in the step of FIG. 4C. Therefore, fluidization of the cobalt silicide crystal grains is suppressed by the protection film 12. Moreover, since the second cobalt silicide film 10b is in an amorphous state, agglomeration of crystal grains does not occur through the second rapid thermal annealing, as in the conventional manufacturing method, and the entirety of the amorphous second cobalt silicide film 10b is converted into the stable third cobalt silicide film 10c made of generally uniform polycrystals. Therefore, partial disruptions are unlikely to occur in the final cobalt silicide film 10c, and it is possible to form the third cobalt silicide film 10c as a single, continuous film having a uniform thickness. Thus, it is possible to reliably realize a reduced resistance in the gate electrode 4 and the heavily-doped source/drain region 7. Moreover, even when the width of the gate electrode or the gate line is reduced, it is possible to avoid partial disruptions from occurring therein, and even when the depth of the heavily-doped source/drain region 7 is reduced, the junction leak can be suppressed because it is possible to obtain a silicide film having a uniform thickness that is made of crystal grains of relatively uniform grain diameters.

Moreover, crystal grains of the third cobalt silicide film 10c grow uniformly during the second rapid thermal annealing by turning the surface portions of the gate electrode 4 and the heavily-doped source/drain region 7 under the first cobalt silicide film b1a into an amorphous state in the process of implanting ions into the first cobalt silicide film b1a. Therefore, it is possible to more effectively realize a reduced resistance in the gate electrode 4, and it is possible to suppress an abnormal junction leak since spiking is less likely to occur under the heavily-doped source/drain region 7.

Note that while the first cobalt silicide film 10a is turned into an amorphous state by implanting arsenic ions in the step of FIG. 4B in the embodiment described above, the first cobalt silicide film 10a may be turned into an amorphous state alternatively by implanting silicon (Si) ions instead of arsenic ions. In the case where silicon ions are implanted, it is possible to compensate for the silicon consumption in the gate electrode 4 and the heavily-doped source/drain region 7 by the reaction of the second rapid thermal annealing, whereby it is possible to suppress the junction leak due to spiking. As a result, the sheet resistance of the third cobalt silicide film 10c is reduced, and it is possible to realize a reduced resistance in the gate electrode 4 and the heavily-doped source/drain region 7. Alternatively, an element that is electrically neutral and capable of turning the first cobalt silicide film 10a into an amorphous state, such as argon (Ar), germanium (Ge) or tin (Sn), may be implanted instead of arsenic. Also in this way, disruptions or substantial surface irregularities in the silicide film due to silicide film agglomeration can be suppressed, as in the case where arsenic ions are implanted.

The timing at which to implant arsenic ions is not limited to the step of FIG. 4C, but may alternatively be the step of FIG. 3C.

When nitrogen ions are implanted, a polycrystalline layered structure will result, as illustrated in the upper right corner of FIG. 4C, through the second rapid thermal annealing. It has been confirmed that, in such a case, agglomeration of the cobalt silicide crystal grains is not likely to occur, unlike in the prior art, even if the second rapid thermal annealing is performed, for the reasons as set forth above in the first embodiment.

In the case where nitrogen is introduced, it is preferred that nitrogen ions are implanted with a dose of 2×10¹⁴ to 2×10¹⁵·cm⁻². When the dose is less than 2×10¹⁴·cm⁻², the effect of suppressing the silicide crystal agglomeration cannot be obtained sufficiently. When the dose is greater than 2×10¹⁵·cm⁻², the interface resistance at the CoSi₂/Si interface increases.

The implanted nitrogen will be introduced not only into the silicide film but also into semiconductor layers (in the present embodiment, the gate electrode 4, the heavily-doped source/drain region 7, the LDD region 5, etc.). It is preferred that the nitrogen concentration in the semiconductor layers (the gate electrode 4, the heavily-doped source/drain region 7 and the LDD region 5) other than the silicide film is 1×10¹⁷·cm⁻³ or less after the formation of the third cobalt silicide film 10c. In other words, it is preferred that a region containing nitrogen at a concentration greater than 1×10¹⁷·cm⁻³ is limited to the silicide film. When the nitrogen concentration is high, the impurities (arsenic, phosphorus, boron, etc.) in the semiconductor layers may not be activated sufficiently, thereby reducing the drain current of the MIS transistor and excessively increasing the sheet resistance of the gate electrode and the gate line.

(Third Embodiment)

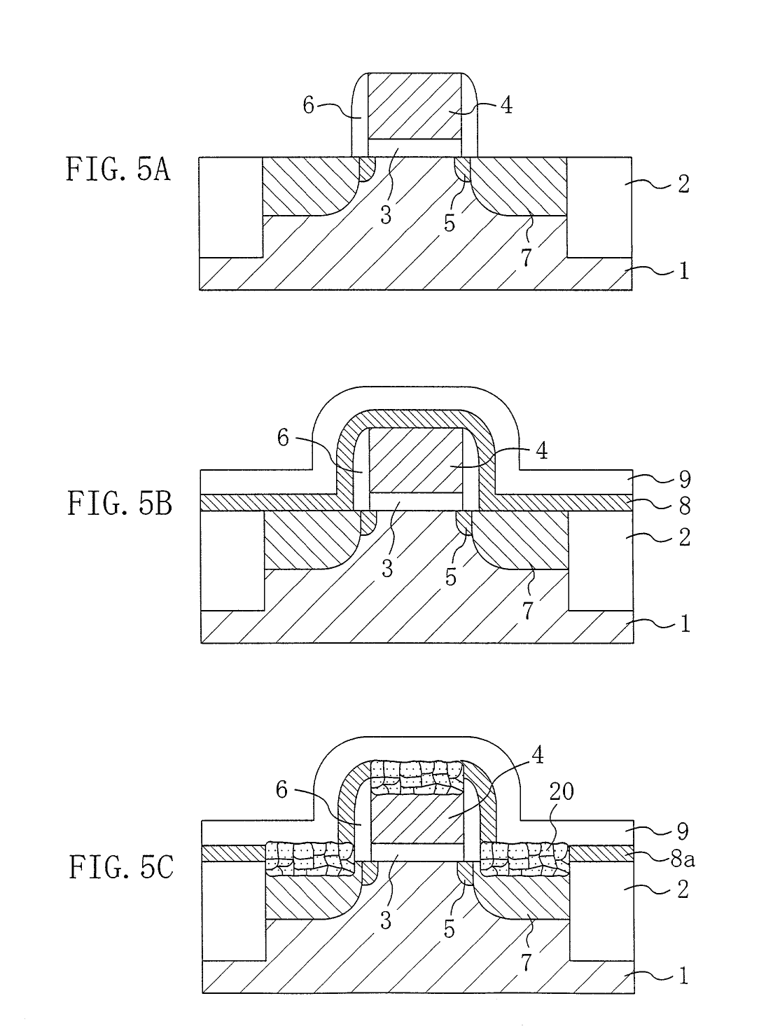

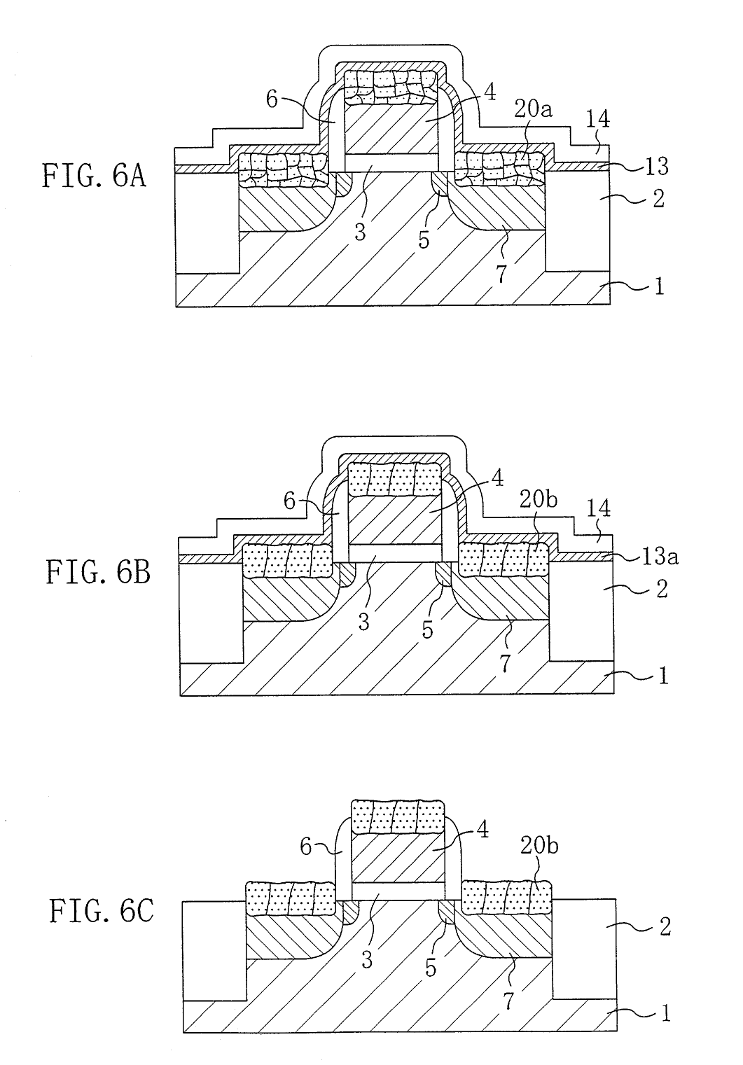

FIG. 5A to FIG. 5C and FIG. 6A to FIG. 6C are cross-sectional views illustrating a method for manufacturing a semiconductor device according to the third embodiment of the present invention.

First, in the step of FIG. 5A, an insulative film 2 for trench device isolation is formed in a p-type semiconductor substrate 1 so as to surround an active region, and a gate insulative film 3 made of a silicon oxide film is formed on the active region of the semiconductor substrate 1. Then, a polysilicon film is deposited on the substrate and patterned by lithography and dry etching so as to form a gate electrode 4 on the gate insulative film 3. Then, a low concentration of n-type impurity ion is implanted into the active region using the gate electrode 4 and the device isolation insulative film 2 as masks so as to form an LDD region 5 in a self-aligned manner with respect to the gate electrode 4. Then, an oxide film is deposited on the substrate by using a CVD method, and the oxide film is etched back so as to form a side wall 6 made of an oxide film on the side surface of the gate electrode 4. Then, a high concentration of n-type impurity ion is implanted into the active region using the gate electrode 4, the side wall 6 and the device isolation insulative film 2 as masks so as to form a heavily-doped source/drain region 7 in a self-aligned manner with respect to the gate electrode 4.

Then, in the step of FIG. 5B, a cobalt film 8 having a thickness of about 8 nm is deposited on the substrate by using a sputtering method, and a titanium nitride film 9 having a thickness of about 20 nm is deposited as a protection film on the cobalt film 8.

Then, in the step of FIG. 5C, the semiconductor substrate 1 is subjected to first rapid thermal annealing (RTA) for about 60 seconds at a temperature of about 400° C. to about 500° C. in a nitrogen gas atmosphere so as to allow silicon (Si) and cobalt (Co) to react with each other to form a cobalt-rich first cobalt silicide film 20a (a mixture of Co₂Si and CoSi) in exposed portions of the gate electrode 4 and the heavily-doped source/drain region 7. In this process, a portion of the cobalt film 8 that is on an insulative film such as the side wall 6 and the device isolation insulative film 2 is not silicified and remains to be an unreacted cobalt film 8a. Note that the first rapid thermal annealing may be performed in a vacuum or an argon atmosphere instead of a nitrogen gas atmosphere.

Then, in the step of FIG. 6A, the titanium nitride film 9 and the unreacted cobalt film 8a are selectively removed by using a solution such as a mixture of sulfuric acid and a hydrogen peroxide solution so as to selectively leave the polycrystalline first cobalt silicide film 20a on the gate electrode 4 and the heavily-doped source/drain region 7. Then, a cobalt film 13 having a thickness of about 2 nm is deposited on the substrate by a sputtering method, as a second metal film thinner than the cobalt film 8, which is the first metal film used for the formation of the first cobalt silicide film 20a, after which a titanium nitride film 14 having a thickness of about 20 nm to be a second protection film is deposited immediately on the cobalt film 13.

Then, in the step of FIG. 6B, the semiconductor substrate 1 is subjected to second rapid thermal annealing (RTA) for about 10 seconds at a temperature of about 800° C. to about 900° C. in a nitrogen gas atmosphere so as to convert the metal-rich first cobalt silicide film 20a into a silicon-rich, structurally-stable second cobalt silicide film 20b (CoSi₂). Although the second rapid thermal annealing causes a silicification reaction to occur between the first cobalt silicide film 20a and the cobalt film 13 thereon, no silicification reaction occurs in portions of the cobalt film 13 that are on the side wall 6 and the device isolation insulative film 2, thereby leaving an unreacted cobalt film 13a. Because the temperature of the second rapid thermal annealing is higher than the temperature of the first rapid thermal annealing, if the second rapid thermal annealing is performed immediately after the first rapid thermal annealing, the cobalt film 8a, which remains unreacted upon completion of the first rapid thermal annealing, is silicified, whereby the gate electrode 4 and the heavily-doped source/drain region 7 may be electrically connected to each other via the silicide film. In contrast, in the present embodiment, the cobalt film 13, which is the second metal film, is as thin as about 2 nm, whereby the second rapid thermal annealing will not entirely silicify the unreacted cobalt film 13a. Note that the second rapid thermal annealing may be performed in a vacuum or an argon atmosphere instead of a nitrogen gas atmosphere.

Then, in the step of FIG. 6C, the titanium nitride film 14 and the unreacted cobalt film 13a are selectively removed by using a solution such as a mixture of sulfuric acid and a hydrogen peroxide solution so as to selectively leave the second cobalt silicide film 20b on the gate electrode 4 and the heavily-doped source/drain region 7.

With the manufacturing method of the present embodiment, the thin cobalt film 13 is deposited on the first cobalt silicide film 20a in the step of FIG. 6A, and then the second rapid thermal annealing is performed in the step of FIG. 6B with the cobalt film 13 being formed across the entire surface. Therefore, partial disruptions are unlikely to occur in the second cobalt silicide film 20b through the second rapid thermal annealing, unlike in the conventional manufacturing method, and it is possible to obtain the stable second cobalt silicide film 20b which is continuous across the entire area. Thus, it is possible to reliably realize a reduced resistance in the gate electrode 4 and the heavily-doped source/drain region 7. Moreover, even when the width of the gate electrode or the gate line is reduced, it is possible to avoid partial disruptions from occurring therein, and even when the depth of the heavily-doped source/drain region 7 is reduced, the junction leak can be suppressed because it is possible to obtain a silicide film having a relatively uniform thickness.

Note that the second embodiment can be applied to the present embodiment by implanting impurity ions into the first silicide film after depositing a second metal film, in which case it is possible to obtain even finer crystal grains.

(Fourth Embodiment)

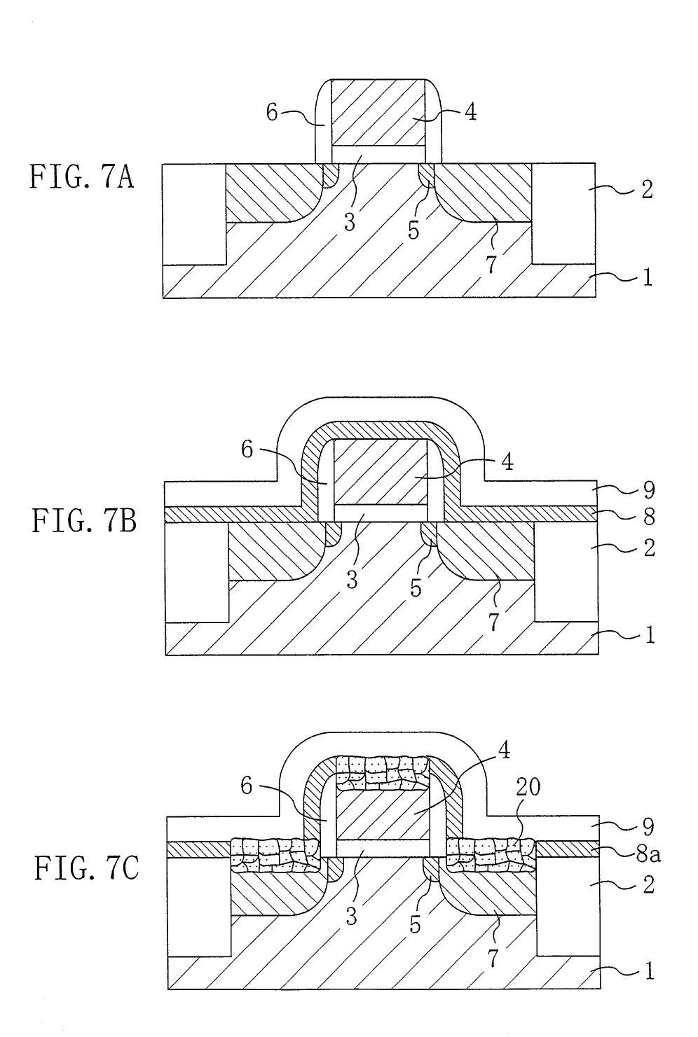

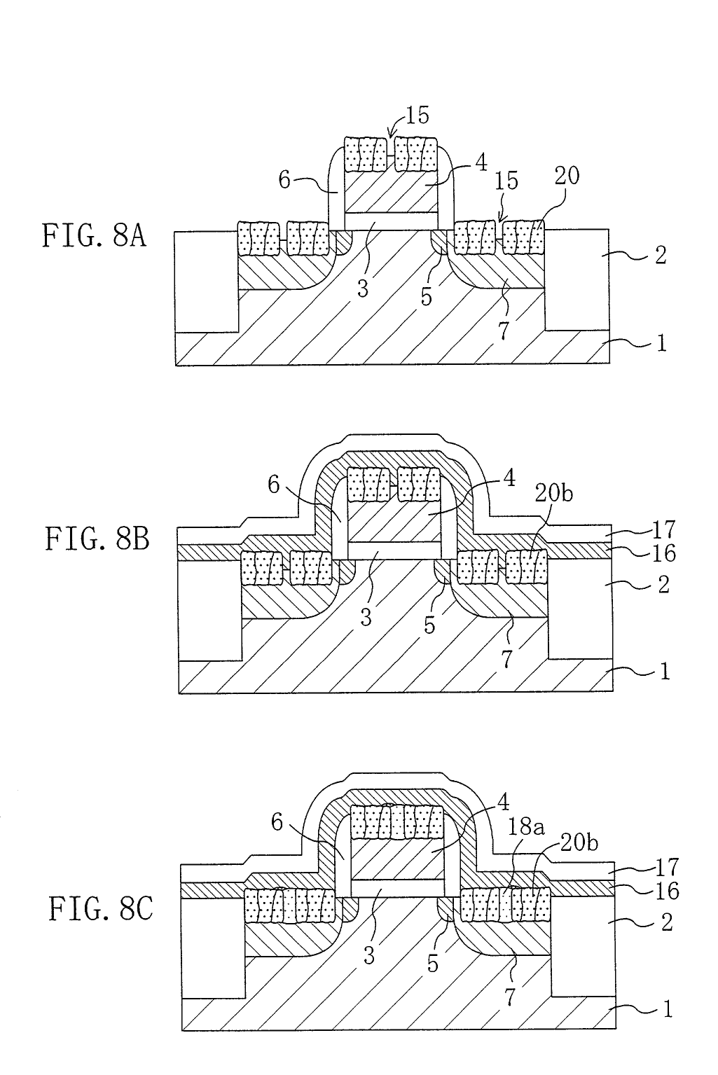

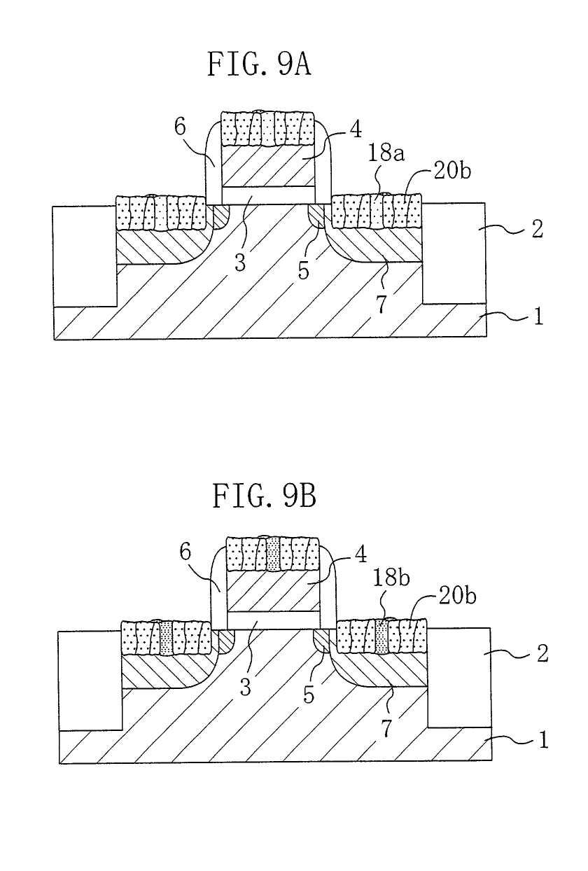

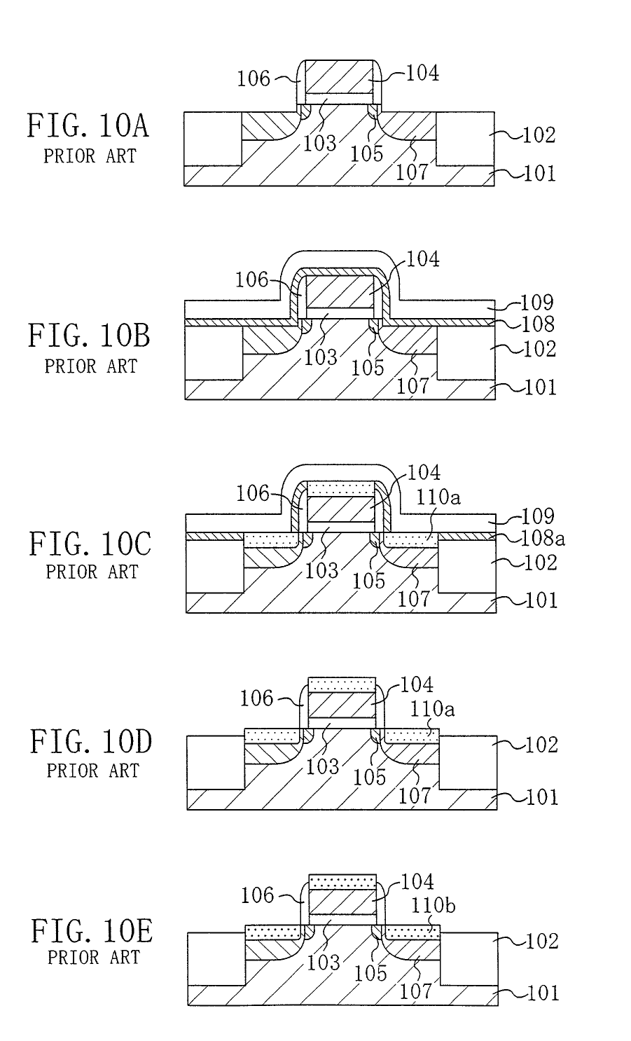

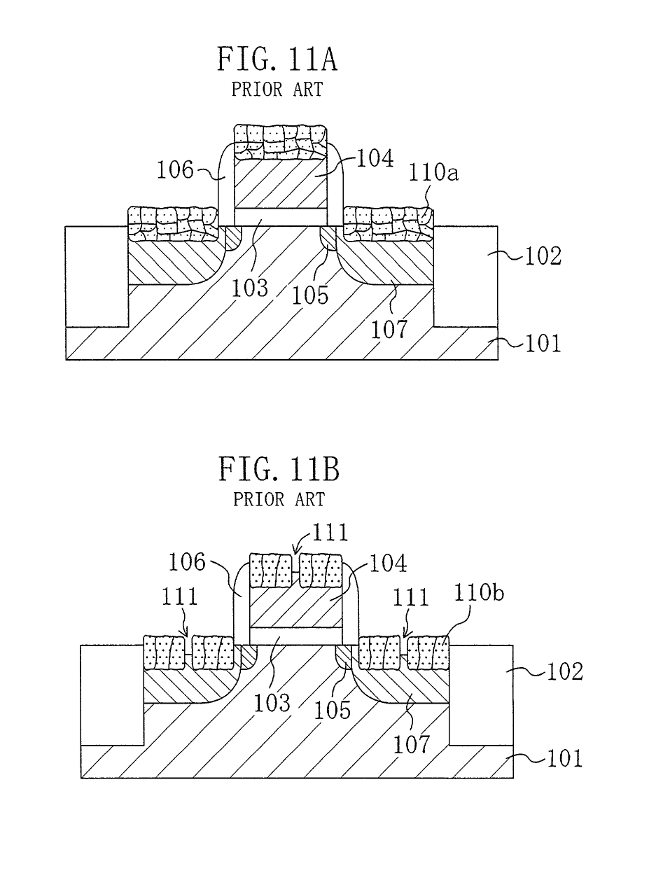

FIG. 7A to FIG. 7C, FIG. 8A to FIG. 8C, and FIG. 9A and FIG. 9B are cross-sectional views illustrating a method for manufacturing a semiconductor device according to the fourth embodiment of the present invention.

First, in the step of FIG. 7A, an insulative film 2 for trench device isolation is formed in a p-type semiconductor substrate 1 so as to surround an active region, and a gate insulative film 3 made of a silicon oxide film is formed on the active region of the semiconductor substrate 1. Then, a polysilicon film is deposited on the substrate and patterned by lithography and dry etching so as to form a gate electrode 4 on the gate insulative film 3. Then, a low concentration of n-type impurity ion is implanted into the active region using the gate electrode 4 and the device isolation insulative film 2 as masks so as to form an LDD region 5 in a self-aligned manner with respect to the gate electrode 4. Then, an oxide film is deposited on the substrate by using a CVD method, and the oxide film is etched back so as to form a side wall 6 made of an oxide film on the side surface of the gate electrode 4. Then, a high concentration of n-type impurity ion is implanted into the active region using the gate electrode 4, the side wall 6 and the device isolation insulative film 2 as masks so as to form a heavily-doped source/drain region 7 in a self-aligned manner with respect to the gate electrode 4.

Then, in the step of FIG. 7B, a cobalt film 8 having a thickness of about 8 nm is deposited on the substrate by using a sputtering method, and a titanium nitride film 9 having a thickness of about 20 nm is deposited as a protection film on the cobalt film 8.

Then, in the step of FIG. 7C, the semiconductor substrate 1 is subjected to first rapid thermal annealing (RTA) for about 60 seconds at a temperature of about 400° C. to about 500° C. in a nitrogen gas atmosphere so as to allow silicon (Si) and cobalt (Co) to react with each other to form a cobalt-rich first cobalt silicide film 20a (a mixture of Co₂Si and CoSi) in exposed portions of the gate electrode 4 and the heavily-doped source/drain region 7. In this process, a portion of the cobalt film 8 that is on an insulative film such as the side wall 6 and the device isolation insulative film 2 is not silicified and remains to be an unreacted cobalt film 8a. Note that the first rapid thermal annealing may be performed in a vacuum or an argon atmosphere instead of a nitrogen gas atmosphere.

Then, in the step of FIG. 8A, the titanium nitride film 9 and the unreacted cobalt film 8a are selectively removed by using a solution such as a mixture of sulfuric acid and a hydrogen peroxide solution so as to selectively leave the polycrystalline first cobalt silicide film 20a on the gate electrode 4 and the heavily-doped source/drain region 7. Then, the semiconductor substrate 1 is subjected to second rapid thermal annealing (RTA) at a temperature of about 800° C. to about 900° C. in a nitrogen gas atmosphere so as to convert the first cobalt silicide film 20a into a structurally-stable second cobalt silicide film 20b (CoSi₂). In this process, the second rapid thermal annealing causes cobalt atoms to move to result in agglomeration of crystal grains, whereby the second cobalt silicide film 20b may become partially excessively thin due to an increase in the crystal grain diameter, or disruptions 15 may occur in the second cobalt silicide film 20b so that the underlying silicon layer is exposed therethrough.

Then, in the step of FIG. 8B, a cobalt film 16 having a thickness of about 6 nm is deposited as a second metal film on the substrate by a sputtering method, and a titanium nitride film 17 having a thickness of about 20 nm is deposited as a second protection film on the cobalt film 16.

Then, in the step of FIG. 8C, the semiconductor substrate 1 is subjected to third rapid thermal annealing (RTA) for about 60 seconds at a temperature of about 400° C. to about 500° C. in a nitrogen gas atmosphere. As a result, silicon (Si) and cobalt (Co) react with each other to form a cobalt-rich third cobalt silicide film 18a (Co₂Si or CoSi) in portions of the gate electrode 4 and the heavily-doped source/drain region 7 that are exposed through the disruptions 15 in the second cobalt silicide film 20b. Although a silicification reaction occurs in this process also between the second cobalt silicide film 20b and the cobalt film 16, the degree of reaction is insignificant as compared to that between the cobalt film 16 and the silicon layer in the disruptions 15 in the second cobalt silicide film 20b. Note that the silicification reaction does not occur in portions of the cobalt film 16 that are on the side wall 6 and the device isolation insulative film 2, thereby leaving an unreacted cobalt film 16a. Note that the third rapid thermal annealing may be performed in a vacuum or an argon atmosphere instead of a nitrogen gas atmosphere.

Then, in the step of FIG. 9A, the titanium nitride film 17 and the unreacted cobalt film 16a are selectively removed by using a solution such as a mixture of sulfuric acid and a hydrogen peroxide solution so as to selectively leave the third cobalt silicide film 18a along with the second cobalt silicide film 20b on the gate electrode 4 and the heavily-doped source/drain region 7.

Then, in the step of FIG. 9B, the semiconductor substrate 1 is subjected to fourth rapid thermal annealing (RTA) for about 10 seconds at a temperature of about 800° C. to about 900° C. in a nitrogen gas atmosphere so as to convert the third cobalt silicide film 18a into a structurally-stable fourth cobalt silicide film 18b (CoSi₂). Note that the fourth rapid thermal annealing may be performed in a vacuum or an argon atmosphere instead of a nitrogen gas atmosphere.

With the manufacturing method of the present embodiment, the structurally-stable second cobalt silicide film 20b is formed through the steps of FIG. 7B, FIG. 7C and FIG. 8A. Then, through the steps of FIG. 8B, FIG. 8C, FIG. 9A and FIG. 9B, even if the disruptions 15 occur during the formation of the second cobalt silicide film 20b, the structurally-stable fourth cobalt silicide film 18b is eventually formed in the disruptions 15. Therefore, it is possible to form a continuous silicide film including the second cobalt silicide film 20b and the fourth cobalt silicide film 18b. As a result, the sheet resistance of the entire silicide film including the second and fourth cobalt silicide films 20b and 18b is reduced, and it is possible to realize a reduced resistance in the gate electrode 4 and the heavily-doped source/drain region 7.

Note that while a cobalt film is used for both the first and second metal films in the embodiment described above, a titanium film and a cobalt film may alternatively be used for the first and second metal films, respectively, so as to form a silicide film including a titanium silicide film and a cobalt silicide film. In such a case, it is preferred that the titanium silicide film is first formed and then the cobalt silicide film is formed, whereby the cobalt silicide film can be formed in the disruptions, through which silicon is exposed, without changing the crystal grain diameter of the titanium silicide film, because the temperature at which agglomeration occurs in the titanium silicide film is higher than the temperature at which agglomeration occurs in the cobalt silicide film.

(Other Embodiments)

While a titanium nitride film is used on a cobalt film in Embodiments 1 to 4, a nitride film or an oxide film may alternatively be used.

Moreover, the semiconductor substrate is not limited to a bulk semiconductor substrate, but may alternatively be an SOI substrate or a semiconductor substrate other than a silicon substrate. Moreover, the semiconductor substrate may be a silicon substrate having a hetero junction in which an SiGe layer and an SiGeC layer are provided.

Furthermore, the members in which a silicide layer is to be formed may be only a gate electrode and a gate line. In such a case, the following two methods may be applicable. The first method is to first pattern a polysilicon film so as to form a gate electrode and a gate line, after which a silicification process is performed. The second method is to deposit a polysilicon film and a metal film and silicify the metal film so as to form a first silicide film, after which the polycide film is patterned so as to form a gate electrode and a gate line. In the case of the second method, the step of forming second and third silicide films of the present invention from a first silicide film may be performed either before or after patterning the polycide film.

Moreover, the members in which a silicide film is to be formed are not limited to a gate electrode and a gate line, but may alternatively be any other member made of a material which can be subjected to a metal silicification process, such as a polysilicon line and a polysilicon electrode (pad). For example, in a DRAM memory cell transistor, a silicide film may be provided only in a gate electrode and a gate line (word line). Also in a general-purpose line or electrode (pad), if a void or a high-resistance portion occurs in a portion thereof due to agglomeration of silicide crystal grains, a defect may occur in the member itself or in the electric connection between the member and a contact member connected to such a portion of the member. Therefore, the present invention can be used with those members, and effects as those described in the embodiments above can be obtained. Moreover, the present invention may be used with a contact to an electrode of a capacitor or to a line of a resistor.

However, it can be said that the present invention is particularly advantageous when it is employed for the formation of a silicide layer on a gate electrode, a gate line or a source/drain region of a MISFET, since members that are very minute are substantially influenced by a void or a thinned portion locally existing in a silicide layer. Of course, the present invention may be employed in a case where a silicide film is formed only in a gate electrode and a gate line, or in a case where a silicide film is formed only in a source/drain region.

Moreover, the present inventor examined the gate line disruption phenomenon to find out that a silicide crystal (cobalt silicide crystal) in the vicinity of a disrupted portion is made of CoSi₂. In view of this, the second rapid thermal annealing is performed in the present invention under conditions such that CoSi₂ crystal grains are unlikely to occur, i.e., at a temperature of 725° C. or less (but higher than the temperature of the first rapid thermal annealing). In this way, it is possible to suppress the disruption (disconnection) in a gate line or a gate line.

However, when the second rapid thermal annealing is performed at a temperature of 725° C. or less, an increase in the junction leak or spiking may occur in the MIS transistor. In view of this, the third rapid thermal annealing is performed at 850° C. for 30 seconds, for example, after covering the silicide film with a protection film such as an oxide film after the second rapid thermal annealing. For example, the third rapid thermal annealing may be performed after a BPSG film, or the like, is deposited as an interlayer insulative film on the substrate, following the step of FIG. 2C. In this way, the third rapid thermal annealing may also serve as a thermal annealing process for reflowing the interlayer insulative film.

Thus, it is possible to suppress the junction leak of a MIS transistor while suppressing the possibility of a gate electrode or a gate line being disrupted due to a reduction in the width thereof.

What is claimed is:

1. A method for manufacturing a semiconductor device including a member which is partially silicified, comprising the steps of:
(a) forming a metal film on a semiconductor layer of a substrate;
(b) performing first thermal annealing to cause a silicification reaction between the metal film and the semiconductor layer so as to form a polycrystalline first silicide film on the semiconductor layer;
(c) removing an unreacted portion of the metal film after the step (b);
(d) implanting impurity ions into the first silicide film so as to change the first silicide film into an amorphous second silicide film;
(e) performing second thermal annealing to change the amorphous second silicide film into a polycrystalline third silicide film, the third silicide film being at least a part of the member.

2. The method for manufacturing a semiconductor device of claim 1, wherein the semiconductor layer is a part of a gate electrode of a MISFET, the method further comprising:
a step of depositing a polysilicon film before the step (a); and
a step of forming the gate electrode before or after the step (a).

3. The method for manufacturing a semiconductor device of claim 1, wherein the semiconductor layer is a part of a source/drain region of a MISFET, the method further comprising, before the step (a):
a step of forming a gate insulative film and a gate electrode on an active region including the semiconductor layer;
a step of forming an insulative side wall on a side surface of the gate electrode; and
a step of forming a source/drain region in each of portions of the active region on both sides of the gate electrode.

4. The method for manufacturing a semiconductor device of claim 1, wherein:
the method further comprises a step of forming a protection film on the substrate after the step (c) and before the step (d); and
in the step (d), ions are implanted into the silicide film via the protection film.

5. The method for manufacturing a semiconductor device of claim 4, wherein the step of forming the protection film is performed at a temperature at which the silicide film does not agglomerate.

6. The method for manufacturing a semiconductor device of claim 4, wherein the step of forming the protection film is performed at a temperature less than or equal to a temperature of the first thermal annealing.

7. The method for manufacturing a semiconductor device of claim 1, wherein in the step (d), the impurity ions are implanted so as to reach into the semiconductor layer to change a surface portion of the semiconductor layer into an amorphous state.

8. The method for manufacturing a semiconductor device of claim 1, wherein in the step (d), electrically neutral ions are used as the impurity ions.

9. The method for manufacturing a semiconductor device of claim 8, wherein in the step (d), silicon ions are used as the electrically neutral ions.

10. A method for manufacturing a semiconductor device including a member which is partially silicified, comprising the steps of:
(a) forming a first metal film on a semiconductor layer of a substrate;
(b) performing first thermal annealing to cause a silicification reaction between the first metal film and the semiconductor layer so as to form a metal-rich first silicide film on the semiconductor layer;
(c) removing an unreacted portion of the first metal film after the step (b);
(d) depositing a second metal film thinner than the first metal film on the substrate after the step (c);
(e) performing second thermal annealing to form a second silicide film including a portion of the first silicide film that has been changed into a silicon-rich structure and a portion of the second metal film that has been silicified, the second silicide film being at least a part of the member; and
(f) performing third thermal annealing to cause a silicification reaction between the second metal film and the semiconductor layer so as to form a third silicide film on the semiconductor layer.

11. The method for manufacturing a semiconductor device of claim 10, wherein the semiconductor layer is a part of a gate electrode of a MISFET, the method further comprising:
a step of depositing a polysilicon film before the step (a); and
a step of forming the gate electrode before or after the step (a).

12. The method for manufacturing a semiconductor device of claim 10, wherein the semiconductor layer is a part of a source/drain region of a MISFET, the method further comprising, before the step (a):
a step of forming a gate insulative film and a gate electrode on a substrate region including the semiconductor layer;
a step of forming an insulative side wall on a side surface of the gate electrode; and
a step of forming a source/drain region in each of portions of the substrate region on both sides of the gate electrode.

13. The method for manufacturing a semiconductor device of claim 10, wherein:
the third silicide film is a metal-rich silicide film; and
the method further comprises a step of, after the step (f), performing fourth thermal annealing to change the third silicide film into a silicon-rich fourth silicide film, the second silicide film and the fourth silicide film being at least a part of the member.

14. A method for manufacturing a semiconductor device including a member which is partially silicified, comprising the steps of:
(a) forming a first metal film on a semiconductor layer of a substrate;
(b) performing first thermal annealing to cause a silicification reaction between the first metal film and the semiconductor layer so as to form a metal-rich first silicide film on the semiconductor layer;
(c) removing an unreacted portion of the first metal film after the step (b);
(d) performing second thermal annealing to change the first silicide film into a silicon-rich second silicide film;
(e) depositing a second metal film on the substrate after the step (d);
(f) performing third thermal annealing to cause a silicification reaction between the second metal film and the semiconductor layer so as to form a metal-rich third silicide film on the semiconductor layer; and
(g) performing fourth thermal annealing to change the third silicide film into a silicon-rich fourth silicide film, the second silicide film and the fourth silicide film being at least a part of the member.

15. The method for manufacturing a semiconductor device of claim 14, wherein the semiconductor layer is a part of a gate electrode of a MISFET, the method further comprising:
a step of depositing a polysilicon film before the step (a); and
a step of forming the gate electrode before or after the step (a).

16. The method for manufacturing a semiconductor device of claim 14, wherein the semiconductor layer is a part of a source/drain region of a MISFET, the method further comprising, before the step (a):
a step of forming a gate insulative film and a gate electrode on a substrate region including the semiconductor layer;
a step of forming an insulative side wall on a side surface of the gate electrode; and
a step of forming a source/drain region in each of portions of the substrate region on both sides of the gate electrode.

17. The method for manufacturing a semiconductor device of claim 14, wherein:
in the step (f), a disruption occurs in the second silicide film when the first silicide film is changed into the second silicide film so that a part of the semiconductor layer is exposed therethrough; and
in the step (g), a silicification reaction is caused between the exposed part of the semiconductor layer and the second metal film.

18. The method for manufacturing a semiconductor device of claim 14, wherein:
in the step (a), a titanium film is formed as the first metal film; and
in the step (g), a cobalt film is formed as the second silicide film.

19. A method for manufacturing a semiconductor device including a member which is partially silicified, comprising the steps of:
(a) forming a metal film whose main component is cobalt on a semiconductor layer of a substrate;
(b) performing first thermal annealing to cause a silicification reaction between the metal film and the semiconductor layer so as to form a polycrystalline first cobalt silicide film on the semiconductor layer;
(c) removing an unreacted portion of the metal film after the step (b); and
(d) after the step (c), performing second thermal annealing at a temperature of 725° C. or less to change the first cobalt silicide film into a second cobalt silicide film, the second cobalt silicide film being at least a part of the member.

20. The method for manufacturing a semiconductor device of claim 19, further comprising:
a step of forming a protection film on the substrate so as to cover the second cobalt silicide film after the step (d); and
a step of performing third thermal annealing at a temperature higher than that of the second thermal annealing, with the second cobalt silicide film being covered by the protection film.

21. A method for manufacturing a semiconductor device including a member which is partially silicified, comprising the steps of:
(a) forming a metal film on a semiconductor layer of a substrate;
(b) performing first thermal annealing to cause a silicification reaction between the metal film and the semiconductor layer so as to form a polycrystalline first silicide film on the semiconductor layer;
(c) removing an unreacted portion of the metal film after the step (b);
(d) introducing nitrogen into the first silicide film before, in, or after, any of the steps (a) to (c); and
(e) after the step (d), performing second thermal annealing to change the first silicide film into a second silicide film, the second silicide film being at least a part of the member.

22. The method for manufacturing a semiconductor device of claim 21, wherein in the step (d), the nitrogen is introduced so that a nitrogen concentration in the semiconductor layer is 10¹⁷·cm⁻³ or less after the step (e).

23. The method for manufacturing a semiconductor device of claim 19, wherein the semiconductor layer is a part of a source/drain region of a MISFET, the method further comprising, before the step (a):
a step of forming a gate insulative film and a gate electrode on an active region including the semiconductor layer;
a step of forming an insulative side wall on a side surface of the gate electrode; and
a step of forming a source/drain region by implanting impurity ions into each of portions of the active region on both sides of the gate electrode and then activating the impurity,
wherein the step (d) is performed after the step of forming a source/drain region and before the step (a).

24. The method for manufacturing a semiconductor device of claim 19, further comprising a pre-cleaning step of irradiating a surface of the semiconductor layer with plasma before the step (a),
wherein the step (d) is performed by introducing nitrogen into the semiconductor layer, in advance, by using nitrogen-containing plasma in the pre-cleaning step.

25. A semiconductor device, comprising:
a substrate including a semiconductor layer; and
a silicide layer formed on the semiconductor layer, the silicide layer being obtained by combining together a first metal silicide film and a second metal silicide film.

26. The semiconductor device of claim 25, wherein the semiconductor layer and the silicide layer together form a gate electrode of a MISFET.

27. The semiconductor device of claim 25, wherein the semiconductor layer and the silicide layer together form a source/drain region of a MISFET.

28. The semiconductor device of claim 25, wherein:
the first metal silicide film includes a disruption due to agglomeration of crystal grains; and
the second metal silicide film is formed at least in the disruption in the first metal silicide film.

29. The semiconductor device of claim 25, wherein:
the first metal silicide film is a titanium silicide film; and
the second metal silicide film is a cobalt silicide film.

30. A semiconductor device, comprising:
a substrate including a semiconductor layer; and
a silicide layer formed on the semiconductor layer and containing nitrogen.

31. The semiconductor device of claim 30, wherein the silicide film is a cobalt silicide film.

32. A semiconductor device comprising:
a substrate including a semiconductor layer; and
a silicide layer formed on the semiconductor layer and having a polycrystalline layered structure.

33. The semiconductor device of claim 32, wherein the silicide film is a cobalt silicide film.
